(19) United States
(12) Patent Application Publication
(10) Pub. No.: US 2023/0058343 A1
(43) Pub. Date: Feb. 23, 2023

(54) NMOS LOW SWING VOLTAGE MODE TX DRIVER

(71) Applicant: NXP USA, Inc., Austin, TX (US)

(72) Inventors: Siamak DELSHADPOUR, Phoenix, AZ (US); Xu Zhang, Chandler, AZ (US); Xiaoquin Liu, Chandler, AZ (US)

(73) Assignee: NXP USA, Inc.

(21) Appl. No.: 17/406,405

(22) Filed: Aug. 19, 2021

(51) Int. Cl. H03K 19/0175; H04L 25/02

(52) U.S. Cl. CPC H03K 19/017545; H04L 25/0278; H03K 19/017509; H04L 25/028

(57) ABSTRACT

Various embodiments relate to a transmit driver circuit, including: a first node connected to a first differential output; a first transistor connected in series with a first resistor, wherein the series connected first transistor and first resistor are connected between a source voltage and the first node; a second transistor connected in series with a second resistor, wherein the series connected second transistor and second resistor are connected between the first node and a ground; a second node connected to a second differential output; a third transistor connected in series with a third resistor, wherein the series connected third transistor and third resistor are connected between the source voltage and the second node; a fourth transistor connected in series with a fourth resistor, wherein the series connected fourth transistor and fourth resistor are connected between the second node and the ground; a first differential input connected to the gate of the first transistor and the gate of the fourth transistor; and a second differential input connected to the gate of the second transistor and the gate of the third transistor, wherein the first transistor, second transistor, third transistor, and fourth transistor are NMOS transistors.

### TECHNICAL FIELD

Various exemplary embodiments disclosed herein relate generally to an all NMOS low swing voltage mode TX driver.

### SUMMARY

A summary of various exemplary embodiments is presented below. Some simplifications and omissions may be made in the following summary, which is intended to highlight and introduce some aspects of the various exemplary embodiments, but not to limit the scope of the invention. Detailed descriptions of an exemplary embodiment adequate to allow those of ordinary skill in the art to make and use the inventive concepts will follow in later sections.

Various embodiments relate to a transmit driver circuit, including: a first node connected to a first differential output; a first transistor connected in series with a first resistor, wherein the series connected first transistor and first resistor are connected between a source voltage and the first node; a second transistor connected in series with a second resistor, wherein the series connected second transistor and second resistor are connected between the first node and a ground; a second node connected to a second differential output; a third transistor connected in series with a third resistor, wherein the series connected third transistor and third resistor are connected between the source voltage and the second node; a fourth transistor connected in series with a fourth resistor, wherein the series connected fourth transistor and fourth resistor are connected between the second node and the ground; a first differential input connected to the gate of the first transistor and the gate of the fourth transistor; and a second differential input connected to the gate of the second transistor and the gate of the third transistor, wherein the first transistor, second transistor, third transistor, and fourth transistor are NMOS transistors.

Various embodiments are described, transmit driver circuit of claim 1, wherein the first resistor is connected between the voltage source and the first transistor, the second resistor is connected between the first node and the second transistor, the third resistor is connected between the voltage source and the third transistor, and the fourth resistor is connected between the second node and the fourth transistor.

Various embodiments are described, transmit driver circuit of claim 1, wherein the first resistor is connected between the first transistor and the first node, the second resistor is connected between the first node and the second transistor, the third resistor is connected between the third transistor and the second node, and the fourth resistor is connected between the second node and the fourth transistor.

Various embodiments are described, transmit driver circuit of claim 1, wherein the first resistor is connected between the voltage source and the first transistor, the second resistor is connected between the second transistor and the ground, the third resistor is connected between the voltage source and the third transistor, and the fourth resistor is connected between the fourth transistor and the ground.

Various embodiments are described, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

Various embodiments are described, wherein when the first differential input is logic 0 and the second differential input is logic 1, the first transistor and fourth transistor are switched off and the second transistor and the third transistor are turned on and the first output is pulled down to the ground and the second output is pulled up to the source voltage.

Further various embodiments relate to a transmit driver circuit, including: a first node connected to a first differential output; a first transistor connected in series with a first resistor, wherein the series connected first transistor and first resistor are connected between a source voltage and the first node; a second transistor connected in series with a second resistor, wherein the series connected second transistor and second resistor are connected between the first node and a ground; a second node connected to a second differential output; a third transistor connected in series with the first resistor, wherein the series connected third transistor and first resistor are connected between the source voltage and the second node; a fourth transistor connected in series with the second resistor, wherein the series connected fourth transistor and second resistor are connected between the second node and the ground; a first differential input connected to the gate of the first transistor and the gate of the fourth transistor; and a second differential input connected to the gate of the second transistor and the gate of the third transistor, wherein the first transistor, second transistor, third transistor, and fourth transistor are NMOS transistors.

Various embodiments are described, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

Various embodiments are described, wherein when the first differential input is logic 0 and the second differential input is logic 1, the first transistor and fourth transistor are switched off and the second transistor and the third transistor are turned on and the first output is pulled down to the ground and the second output is pulled up to the source voltage.

Further various embodiments relate to a differential high-speed data path circuit, including: a differential gain circuit; a differential transmit driver circuit including a first differential input and a second differential input including: a first node connected to the first differential output; a first transistor connected in series with a first resistor, wherein the series connected first transistor and first resistor are connected between a source voltage and the first node; a second transistor connected in series with a second resistor, wherein the series connected second transistor and second resistor are connected between the first node and a ground; a second node connected to the second differential output; a third transistor connected in series with a third resistor, wherein the series connected third transistor and third resistor are connected between the source voltage and the second node; a fourth transistor connected in series with a fourth resistor, wherein the series connected fourth transistor and fourth resistor are connected between the second node and the ground; a first differential input connected to the gate of the first transistor and the gate of the fourth transistor; and a second differential input connected to the gate of the second transistor and the gate of the third transistor, wherein the first transistor, second transistor, third transistor, and fourth transistor are NMOS transistors.

Various embodiments are described, wherein the first resistor is connected between the voltage source and the first transistor, the second resistor is connected between the first node and the second transistor, the third resistor is connected between the voltage source and the third transistor, and the fourth resistor is connected between the second node and the fourth transistor.

Various embodiments are described, wherein the first resistor is connected between the first transistor and the first node, the second resistor is connected between the first node and the second transistor, the third resistor is connected between the third transistor and the second node, and the fourth resistor is connected between the second node and the fourth transistor.

Various embodiments are described, wherein the first resistor is connected between the voltage source and the first transistor, the second resistor is connected between the second transistor and the ground, the third resistor is connected between the voltage source and the third transistor, and the fourth resistor is connected between the fourth transistor and the ground.

Various embodiments are described, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

Various embodiments are described, wherein when the first differential input is logic 0 and the second differential input is logic 1, the first transistor and fourth transistor are switched off and the second transistor and the third transistor are turned on and the first output is pulled down to the ground and the second output is pulled up to the source voltage.

Further various embodiments relate to a differential high-speed data path circuit, including: a differential gain circuit; a differential transmit driver circuit including a first differential input and a second differential input including: a first node connected to the first differential output; a first transistor connected in series with a first resistor, wherein the series connected first transistor and first resistor are connected between a source voltage and the first node; a second transistor connected in series with a second resistor, wherein the series connected second transistor and second resistor are connected between the first node and a ground; a second node connected to the second differential output; a third transistor connected in series with the first resistor, wherein the series connected third transistor and first resistor are connected between the source voltage and the second node; a fourth transistor connected in series with the second resistor, wherein the series connected fourth transistor and second resistor are connected between the second node and the ground; a first differential input connected to the gate of the first transistor and the gate of the fourth transistor; and a second differential input connected to the gate of the second transistor and the gate of the third transistor, wherein the first transistor, second transistor, third transistor, and fourth transistor are NMOS transistors.

Various embodiments are described, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

Various embodiments are described, wherein when the first differential input is logic 0 and the second differential input is logic 1, the first transistor and fourth transistor are switched off and the second transistor and the third transistor are turned on and the first output is pulled down to the ground and the second output is pulled up to the source voltage.

### BRIEF DESCRIPTION OF THE DRAWINGS

In order to better understand various exemplary embodiments, reference is made to the accompanying drawings, wherein:

FIG. 1 illustrates the high-speed path of a USB2 to eUSB repeater;

FIG. 2 illustrates a typical voltage mode TX driver;

FIG. 3 illustrates a typical current mode TX driver;

FIG. 4 illustrates a fully differential current mode TX driver with its differential load;

FIG. 5 illustrates a fully differential voltage mode TX driver with its differential load;

FIG. 6 illustrates a low swing mode voltage mode TX driver;

FIG. 7 illustrates a low swing mode voltage mode TX driver;

FIG. 8 illustrates a first embodiment of an all NMOS voltage mode TX driver;

FIG. 9 illustrates a second embodiment of an all NMOS voltage mode TX driver;

FIG. 10 illustrates a third embodiment of an all NMOS voltage mode TX driver; and

FIG. 11 illustrates a fourth embodiment of an all NMOS voltage mode TX driver.

To facilitate understanding, identical reference numerals have been used to designate elements having substantially the same or similar structure and/or substantially the same or similar function.

### DETAILED DESCRIPTION

The description and drawings illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be for pedagogical purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments can be combined with one or more other embodiments to form new embodiments.

The embedded USB2 (eUSB2) specification is a supplement to the USB2.0 specification that addresses issues related to interface controller integration with advanced system-on-chip (SoC) process nodes by enabling USB2.0 interfaces to operate at I/O voltages of 1V or 1.2V instead of 3.3V. eUSB2 can enable smaller, more power-efficient SoCs, in turn enabling process nodes to continue to scale while increasing performance in applications such as smartphones, tablets and notebooks.

As applications like smartphones and tablets continue to pack more and more components into smaller form factors, it is essential that interfaces shrink as well. However, the continued shrinking of SoC node size has led to a thinner gate oxide that can only support lower voltages. For devices relying on USB2.0 interfaces, this trend can lead to complicated design challenges for advanced process nodes.

When process nodes reach 7 nm, quantum effects begin impacting high-signaling-voltage inputs/outputs (IOs) such as 3.3V and can no longer be easily supported. Many device-to-device interfaces already support low signaling voltages, but USB2.0 still requires a 3.3V I/O voltage to operate.

USB2.0 has been the most successful wired interface in the past 20 years, and almost all SoCs today are equipped with the USB2.0 interface. USB standards evolution kept the original 3.3V I/O USB 1.0 interface intact for backward compatibility, helping enable wider adoption and a larger ecosystem while also preserving device interoperability.

As process nodes approach smaller features (e.g. 5 nm), the manufacturing cost to maintain USB2.0 3.3V I/O signaling has grown exponentially. eUSB2 addresses the I/O voltage gap as a physical layer supplement to the USB2.0 specification so that designers can integrate the eUSB2 interface at the device level while leveraging and reusing the USB2.0 interface at the system level.

eUSB2 can support onboard inter-device connectivity through direct connections as well as exposed connector interfaces through an eUSB2-to-USB2.0/USB2-to-eUSB2 repeater, to perform level shifting

While USB2.0 can continue to be integrated into SoCs with process features of 7 nm and above, eUSB2 is a good fit for SoCs when process features are 5 nm and below. eUSB2 can also be integrated into other devices to easily interconnect with SoCs as a device-to-device interface. USB2.0 will continue serving as the standard connector interface.

eUSB2 allows significant I/O power reduction and improves power efficiency, while enabling process features to continue to scale.

A USB2 to eUSB2 repeater includes a USB2 port and an eUSB2 port. Bidirectional traffic may be carried by the repeater include low speed (LS), full speed (FS), and high speed (HS) traffic. The repeater may have different voltage domains that serve the different ports. For example, a 1.8V source may be used to power the circuits related to the eUSB2 port, and a 3.3V source may be used to power the circuits related to the USB2 port. Each of the USB2 pins faces ˜3.6V voltage in LS/FS mode and<1.1V signal in HS mode (0.44V in functional mode and<1.1V in chirp mode), so it is assumed that the maximum signal in each of the USB2 pins during the HS-RX mode will be 1.1V).

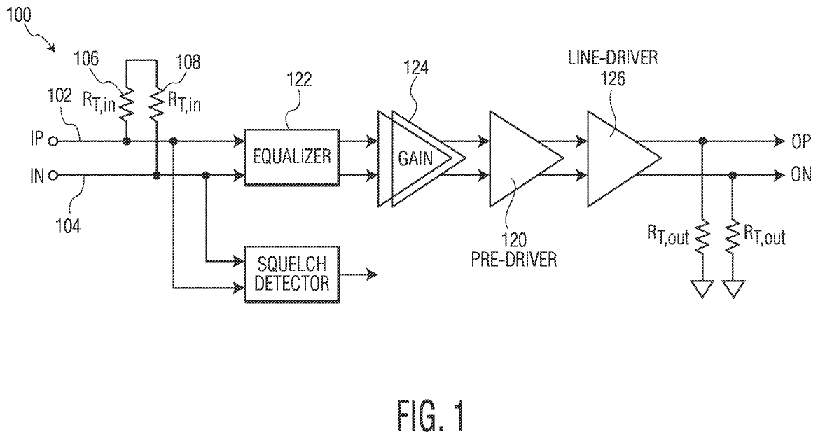

FIG. 1 illustrates the high-speed path of a USB2 to eUSB repeater. The high speed path 100 includes USB2 input pins 102, 104 that receive a differential input signal. Each input pin 102, 104 have a termination resistance 106, 108 respectively terminated to a voltage VT. The resistance of the termination resistors 106, 108 may be selected based upon the specific standards being implemented. The incoming USB2 signal passes through an equalizer 122 that may be a continuous time linear equalizer (CTLE). The output of the equalizer 122 then passes through gain stages 124 to amplify the signal. Next, a pre-driver receives the amplified signal and processes it and outputs it to a transmit (TX) driver 126. The TX driver 126 then transmits the eUSB signal to eUSB pins 132, 134.

The equalizer 122 removes most of the inter-symbol interference (ISI) that is introduced by the transmission channel at its input. The gain stages 124 make a (non-linear) hard decision and makes the equalized signal high or low. That avoids propagation of amplitude noise and allows regeneration of pre-emphasis but turns residual ISI into non-equalizable timing jitter.

The high-speed path 100 may practically be considered for a USB2/eUSB high-speed repeater. The high-speed path 100 illustrates a TX driver 126, but de-emphasis may be added to TX driver 126 as well.

The standard eUSB voltage swing according to the high-speed transmitter DC specification is 400 mV (±10%) that is relatively low swing compared to existing supply voltage (VDD=1.8 V).

Embodiments of a low-swing high-speed voltage mode TX driver featuring an all NMOS design together with resistors for impedance control will be described. The transmitter works in a voltage-mode, which pulls-up or pulls-down signal nets towards a local supply net or a local ground net. NMOS switch devices are used for either pull-up or pull-down operations, controlled by the input signal. Output impedances of the pull-up or pull-down paths are controlled by explicit resistor instances that are in serial to the NMOS switches. Such a configuration simplifies the transmitter design by avoiding additional control loops to regulate switch resistances.

The TX driver embodiments described herein are proposed for an eUSB application, but they may be generalized for any low swing voltage mode transmitter. The TX driver embodiments described herein have the following benefits: use only NMOS transistors for voltage mode TX driver; good for high-speed applications because only NMOS transistors are used (i.e., smaller size compared to a NMOS+PMOS transistor version, less parasitic capacitors, etc.); less area consumed due to avoiding PMOS switches; good for implementing the eUSB standard (and any other voltage mode standard); better matching and equally less variation for the output impedance; less swing variation over process/voltage/temperature (PVT) due to improved matching;

The TX driver embodiments described herein reduce the need for PMOS transistors in a voltage-mode driver (with or without de-emphasis). The TX driver embodiments described herein also is suitable for high-speed applications.

The differences between voltage mode and current mode TX drivers will now be described. Signal integrity considerations (e.g., minimum reflections) require 40Ω driver output impedance (for eUSB but this may vary for different standard as was mentioned above).

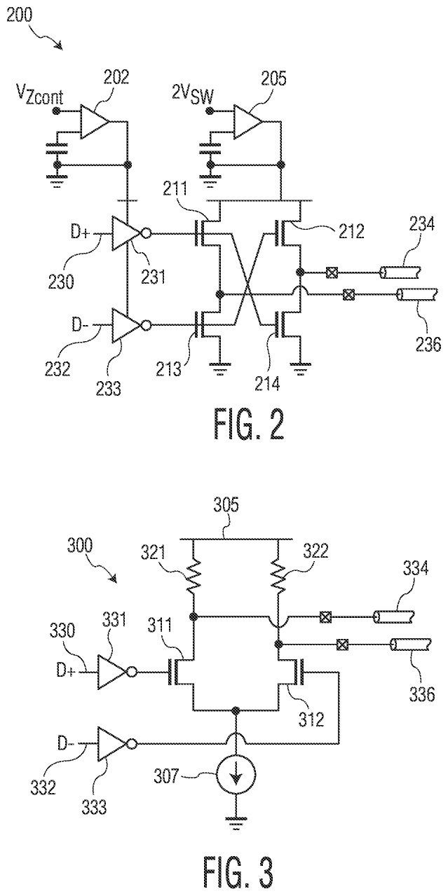

FIG. 2 illustrates a typical voltage mode TX driver. The voltage mode TX driver 200 includes four transistors 211, 212, 213, 214 that are connected to a volage source 205. Inputs 230, 232 received by inverters 221, 233, respectively, control the transistors 211, 212, 213, 214 so that an output is generated at the outputs 234, 236 based upon the input voltage received. Voltage-mode drivers use Thevenin-equivalent series termination and potentially ½ to ¼ the current as in a current-mode TX driver for a given output swing

FIG. 3 illustrates a typical current mode TX driver. The current mode TX driver 300 includes two transistors 311, 312 that are connected to a voltage source 305 and a current source 307. Inputs 330, 332 received by inverters 331, 333, respectively, control the transistors 311, 312 so that the output is generated at the outputs 334, 336 based upon the input voltage received. Current-mode drivers use Norton-equivalent parallel termination and using them is much easier to control output impedance.

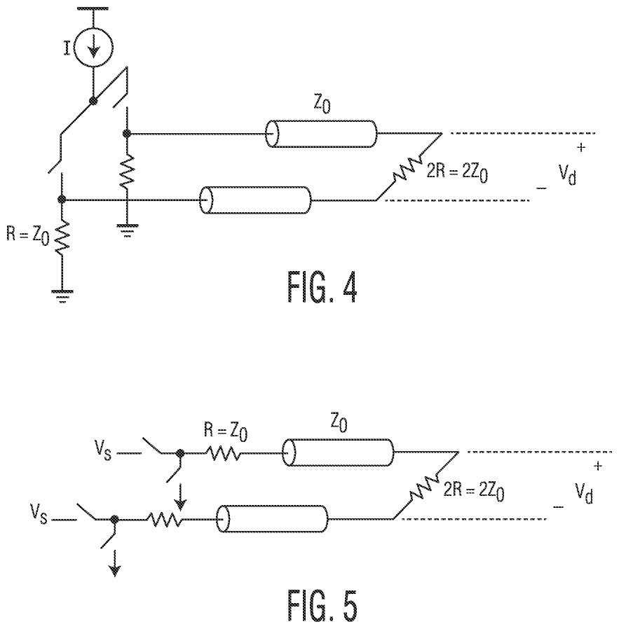

Differential termination current mode current levels will first be described. FIG. 4 illustrates a fully differential current mode TX driver with its current consumption with the flowing voltages and currents:

V_{d,+}=(I/4)(2R);

V_{d,-}=−(I/4)(2R);

V_{d,pp}=IR; and

$$I = \frac{{V}_{d , pp}}{R} .$$

Differential termination voltage mode current levels will next be described. FIG. 5 illustrates a fully differential voltage mode TX driver with its current consumption with the flowing voltages and currents:

V_{d,+}=(Vₛ/2);

V_{d,-}=−(Vₛ/2);

V_{d,pp}=Vₛ; and

$$I = \frac{{V}_{d , pp}}{4 R} .$$

Table 1 shows relative current consumption of single ended and fully differential current mode and voltage mode TX driver.

TABLE 1

| Driver/Termination | Current Level | Normalized Current Level |
|---|---|---|
| Current-mode/SE | V_{d,pp}/Z₀ | 1× |
| Current-mode/Diff | V_{d,pp}/Z₀ | 1× |
| Voltage-mode/SE | V_{d,pp}/2Z₀ | 0.5× |
| Voltage-mode/Diff | V_{d,pp}/4Z₀ | 0.25× |

An ideal voltage-mode driver with differential RX termination enables a potential 4×reduction in TX driver current. Actual TX driver power levels also depend on output impedance control, pre-driver power, and equalization implementation.

Low swing and high swing voltage mode TX drivers will now be described. FIG. 6 illustrates a low swing mode voltage mode TX driver 600. The TX driver 600 has the same basic structure and function as the TX driver 200 in FIG. 2. The TX driver 600 uses all NMOS transistors 611, 612, 613, 614.

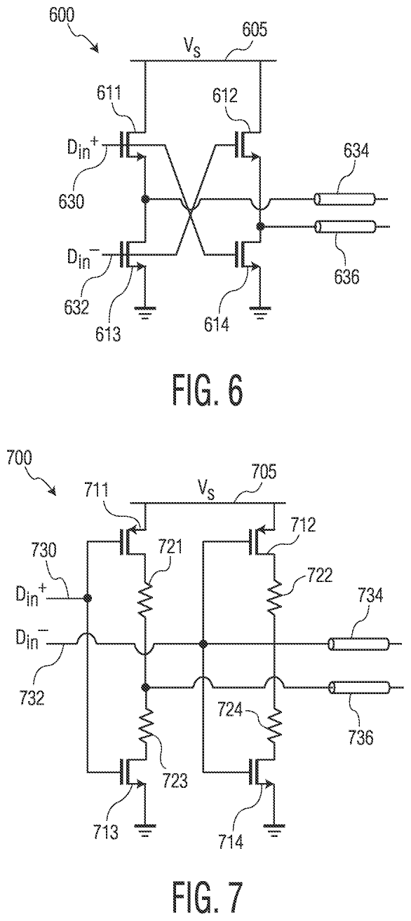

FIG. 7 illustrates a low swing mode voltage mode TX driver 700. The TX driver 700 has four transistors 711, 712, 713, 714. Transistors 711 and 713 are connected in series with resistors 721 and 723 between the source voltage V_{S} 705 and ground as shown. Further, transistors 712 and 714 are connected in series with resistors 722 and 724 between the source voltage Vₛ 705 and ground. The input 730 controls the operation of transistors 711 and 713 to produce the output 736. The input 732 controls the operation of transistors 712 and 714 to produce the output 734. Transistors 711 and 712 are PMOS transistors, and transistors 713 and 714 are NMOS transistors.

The voltage-mode driver implementation depends on output swing requirements. For low-swing (<400-500 mVpp), an all NMOS driver is suitable, while for high-swing, a driver with both PMOS and NMOS transistors is used.

For the low swing embodiment with differential termination:

$${V}_{S} < \frac{4}{3} ( VDD - {V}_{t 1} - {V}_{OD 1} ) .$$

For the high swing embodiment with differential termination:

V_{S}>|Vₜ₁|+V_{OD1}.

V_{S} is the supply voltage which is twice of the final swing of the differential voltage mode driver. Vₜ₁ is the threshold voltage of the transistors, and V_{OD1} is the overdrive voltage of the transistors (V_{OD1}=V_{G}−Vₜ₁).

To get an equal Rₒₙ for a PMOS switch, its size should be approximately 2.5-3 times of size of a NMOS switch (depending on the technology/process node). This means that the resulting parasitic capacitances will also be greater which will greatly reduce the speed of the driver.

In the voltage mode TX driver, because Rₒₙ of the switch will be added to the Rₒᵤₜ, its variation will be added to range of Rₒᵤₜ. Considering different variations for PMOS and NMOS transistors, a wider Rₒᵤₜ range will be expected which will be reduced by using an NMOS only solution. Due to limited swing of the output, using NMOS switches in the top and bottom sides of the TX driver seems to be a better solution which is a key point of the embodiments described herein.

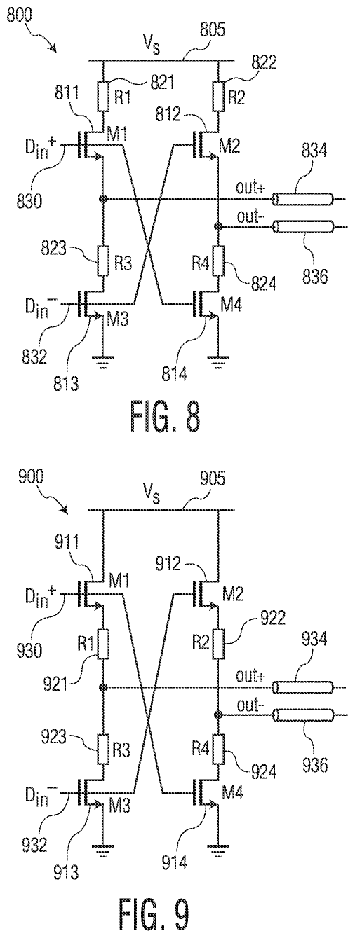

Various embodiments of all NMOS voltage mode TX drivers will now be described. FIG. 8 illustrates a first embodiment of an all NMOS voltage mode TX driver. The TX driver includes NMOS transistors M1 811, M2 812, M3 813, and M4 814. The TX driver 800 also includes resistors R1 821, R2 822, R3 823, and R4 824. The TX driver 800 also includes differential inputs Din+830 and Din−832 and differential outputs out+834 and out−836. M1 811, R1 821, M2 812, and R2 822 form two pull-up paths. M3 813, R3 823, M4 814, and R4 824 form two pull-down paths. When the differential input 830, 832 is at logic high, meaning Din+=1 and Din−=0, then M1 811 and M4 814 are switched on and M2 812 and M3 813 are switched off. Thus, out+834 is pulled-up to Vs by M1 811 and R1 821. Also, out−836 is pulled-down to ground by M4 814 and R4 824. Similarly, when the differential input 830, 832 is at logic low, M2 812 and M3 813 are switched on and M1 811 and M4 814 are switched off. As a result, out+834 is pulled-down to ground and out−836 is pulled-up to Vs. The NMOS transistors M1 811, M2 812, M3, 813, and M4 814 are sized to have switch resistances much lower than the resistors R1 821, R2 822, R3 823, and R4 824 FIG. 8. Consequently, the impedance of pull-up or pull-down paths are dominated by the resistor components. This avoids the need for additional feedback loops to control the switch resistances of M1 811, M2 812, M3, 813, and M4 814 for matching purpose. In the eUSB application, such a signal-ended impedance is 40Ω. It is 50Ω for most other high-speed applications. The pull-up paths have the source terminals of M1 811 and M2 812 connected to the output pins directly to have the maximum possible Vgs for M1 811 and M2 812. Thus, the device sizes of M1 811 and M2 812 may be reduced to achieve certain switch resistance value.

FIG. 9 illustrates a second embodiment of an all NMOS voltage mode TX driver. The pull-up paths may have the resistors R1 921, R2 922, R3 923, and R4 924 connected to output pins 934, 936 directly as shown in FIG. 9. The various elements of the TX driver 900 of FIG. 9 are similar to the TX driver 800 (of FIG. 8) where similar numbers are used for similar elements. In TX driver 900 the source terminals of the top NMOSs M1 911 and M2 912 are not connected to output pins 934, 936 directly. As a result, M1 911 and M2 912 may tolerate higher ESD stress. However, voltages between input pins 930, 932 and output pins 934, 936 see additional voltage drops of IR due to the resistors. The maximum Vgs of M1 911 or M2 912 is reduced. This results in an area penalty for M1 911 and M2 912 to achieve the same switch resistance as the TX driver 800 in FIG. 8.

A transmitter in real applications usually includes multiple unit cells as shown in FIG. 8 and FIG. 9. The number of the unit cells can be changed to control the output swing, pre/de-emphasis level and impedance of the transmitter. If variations of the resistors in the TX drivers 800 and 900 can be controlled precisely from manufacturing, impedance trimming can be avoided to further simplify the design.

FIG. 10 illustrates a third embodiment of an all NMOS voltage mode TX driver. The various elements of the TX driver 1000 of FIG. 10 are similar to the TX driver 800 where similar numbers are used for similar elements. The resistors R1 921, R2 922, R3 923, and R4 924 of FIG. 9 may be moved up and down to result in the circuit of FIG. 10.

In the TX driver 1000 of FIG. 10, only one of transistor pair M1 1011 and M2 1012 is enabled at a time. This means that one resistor can be used instead of R1 1021 and R2 1022. Also considering the transistor pair M3 1013 and M4 1014, only one of them is enabled at a time. This means that one resistor can be used instead of R3 1023 and R4 1024 as well.

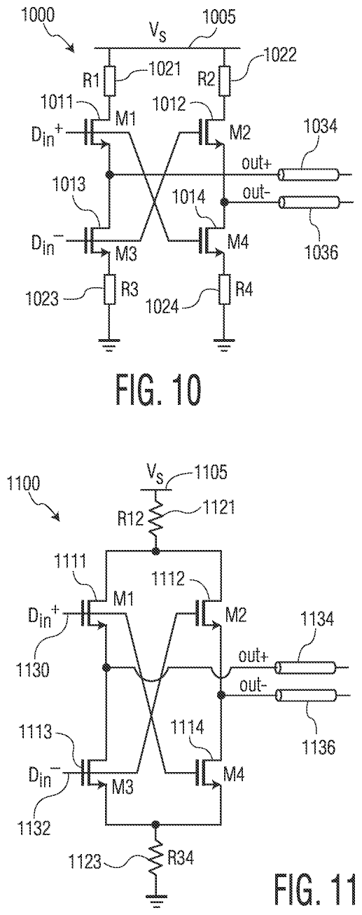

FIG. 11 illustrates a fourth embodiment of an all NMOS voltage mode TX driver. The TX driver 1100 of FIG. 11 illustrates this more simplified and efficient architecture where M1 1111 and M2 1112 share R12 1121 and M3 1113 and M4 1114 share R34 1123.

The all NMOS TX drivers described herein may be used for a low-swing high speed voltage mode TX driver using an all NMOS design together with resistors for impedance control. The use of the resistors control the output impedances of the pull-up or pull-down path, so that additional control loops are not needed to regulate switch resistances. The TX drivers described herein may be used in various low swing voltage mode applications.

It should be appreciated by those skilled in the art that any block diagrams herein represent conceptual views of illustrative circuitry embodying the principles of the invention.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the claims.

1. (canceled)

2. (canceled)

3. (canceled)

4. (canceled)

5. (canceled)

6. (canceled)

7. A transmit driver circuit, comprising:
a first node connected to a first differential output;
a first transistor connected in series with a first resistor, wherein the series connected first transistor and first resistor are connected between a source voltage and the first node;
a second transistor connected in series with a second resistor, wherein the series connected second transistor and second resistor are connected between the first node and a ground;
a second node connected to a second differential output;
a third transistor connected in series with the first resistor, wherein the series connected third transistor and first resistor are connected between the source voltage and the second node;
a fourth transistor connected in series with the second resistor, wherein the series connected fourth transistor and second resistor are connected between the second node and the ground;
a first differential input connected to the gate of the first transistor and the gate of the fourth transistor; and
a second differential input connected to the gate of the second transistor and the gate of the third transistor,
wherein the first transistor, second transistor, third transistor, and fourth transistor are NMOS transistors.

8. The transmit driver circuit of claim 7, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

9. The transmit driver circuit of claim 7, wherein when the first differential input is logic 0 and the second differential input is logic 1, the first transistor and fourth transistor are switched off and the second transistor and the third transistor are turned on and the first output is pulled down to the ground and the second output is pulled up to the source voltage.

10. (canceled)

11. (canceled)

12. (canceled)

13. (canceled)

14. (canceled)

15. (canceled)

16. A differential high-speed data path circuit, comprising:
a differential gain circuit;
a differential transmit driver circuit including a first differential input and a second differential input comprising:
a first node connected to the first differential output;
a first transistor connected in series with a first resistor, wherein the series connected first transistor and first resistor are connected between a source voltage and the first node;
a second transistor connected in series with a second resistor, wherein the series connected second transistor and second resistor are connected between the first node and a ground;
a second node connected to the second differential output;
a third transistor connected in series with the first resistor, wherein the series connected third transistor and first resistor are connected between the source voltage and the second node;
a fourth transistor connected in series with the second resistor, wherein the series connected fourth transistor and second resistor are connected between the second node and the ground;
a first differential input connected to the gate of the first transistor and the gate of the fourth transistor; and
a second differential input connected to the gate of the second transistor and the gate of the third transistor,
wherein the first transistor, second transistor, third transistor, and fourth transistor are NMOS transistors.

17. The differential high-speed data path circuit of claim 16, wherein when the first differential input is logic 1 and the second differential input is logic 0, the first transistor and fourth transistor are switched on and the second transistor and the third transistor are turned off and the first output is pulled up to the source voltage and the second output is pulled down to the ground.

18. The differential high-speed data path circuit of claim 16, wherein when the first differential input is logic 0 and the second differential input is logic 1, the first transistor and fourth transistor are switched off and the second transistor and the third transistor are turned on and the first output is pulled down to the ground and the second output is pulled up to the source voltage.
